(19) United States
(12) Patent Application Publication
(10) Pub. No.: US 2022/0076992 A1
(43) Pub. Date: Mar. 10, 2022

(54) SEMICONDUCTOR STRUCTURE FOR DIGITAL AND RADIOFREQUENCY APPLICATIONS

(71) Applicant: Soitec, Bernin (FR)

(72) Inventors: Yvan Morandini, La Trinite (US); Walter Schwarzenbach, Saint Nazaire Les Eymes (FR); Frédéric Allibert, Grenoble (FR); Eric Desbonnets, Lumbin (FR); Bich-Yen Nguyen, Austin, TX (US)

(73) Assignee: Soitec, Bernin (FR)

(21) Appl. No.: 17/417,715

(22) PCT Filed: Dec. 23, 2019
(86) PCT No.: PCT/FR2019/053280

§ 371 Date: Jun. 23, 2021

(30) Foreign Application Priority Data
Dec. 24, 2018 (FR) 1874137

(51) Int. Cl. H01L 21/762; H01L 21/02; H01L 21/322; H01L 27/12; H01L 29/06

(52) U.S. Cl. CPC H01L 21/76254; H01L 21/76281; H01L 29/0649; H01L 21/3226; H01L 27/1207; H01L 21/0262

(57) ABSTRACT

A semiconductor-on-insulator multilayer structure, comprises: —a stack, called the back stack, of the following layers from a back side to a front side of the structure: a semiconductor carrier substrate the electrical resistivity of which is between 500 Ω·cm and 30 kΩ·cm, a first electrically insulating layer, a first semiconductor layer, —at least one trench isolation that extends through the back stack at least down to the first electrically insulating layer), and that electrically isolates two adjacent regions of the multilayer structure, the multilayer structure being characterized in that it further comprises at least one FD-SOI first region, and at least one RF-SOI second region.

### CROSS-REFERENCE TO RELATED APPLICATIONS

This application is a national phase entry under 35 U.S.C. § 371 of International Patent Application PCT/FR2019/053280, filed Dec. 23, 2019, designating the United States of America and published as International Patent Publication WO 2020/136343 A1 on Jul. 2, 2020, which claims the benefit under Article 8 of the Patent Cooperation Treaty to French Patent Application Serial No. 1874137, filed Dec. 24, 2018.

### TECHNICAL FIELD

The present disclosure relates to a semiconductor-on-insulator structure for digital and radiofrequency applications. The present disclosure also relates to a process for fabricating such a structure via transfer of a layer from a first substrate, called the “donor substrate”, to a second substrate, called the “receiver substrate”.

### BACKGROUND

Semiconductor-on-insulator structures are multilayer structures comprising a substrate, which is generally made of silicon, an electrically insulating layer arranged on top of the substrate, which is generally a layer of oxide such as a layer of silicon oxide, and, arranged on top of the insulating layer, a semiconductor layer in which the source, the channel and drain of the transistors are produced and which is generally a layer of silicon.

Semiconductor-on-insulator (SeOI) structures are referred to as “silicon-on-insulator” (SOI) structures when the semiconductor is silicon.

Among existing SOI structures, fully-depleted silicon-on-insulator (FD-SOI) structures are commonly used for digital applications. FD-SOI structures are characterized by the presence of a thin oxide layer, arranged on a silicon substrate, and of a very thin semiconductor layer called the SOI layer arranged on the oxide layer.

The oxide layer is located between the substrate and the SOI layer. The oxide layer is then said to be “buried”, and is called the “BOX” for Buried OXide.

The SOI layer allows the conduction channel to be formed in the FD-SOI structure.

Because of the small thickness and of the uniformity of the BOX layer and of the SOI layer, it is not necessary to dope the conduction channel, and hence the structure is able to operate in a fully depleted mode.

FD-SOI structures have improved electrostatic characteristics with respect to structures without BOX layers. The BOX layer decreases the parasitic electrical capacitance between the source and drain, and also allows leakage of electrons from the conduction channel to the substrate to be considerably decreased by confining the flow of electrons to the conduction channel, thus decreasing current losses and improving the performance of the structure.

FD-SOI structures can be compatible with radiofrequency (RF) applications, but however suffer from the appearance of electrical losses in the substrate.

To compensate for these electrical losses and improve RF performance, it is known to use a substrate, in particular, an SOI substrate, having a high electrical resistivity, this type of substrate commonly being referred to as an “HR substrate” for high-resistivity substrate. The latter is advantageously combined with a charge-trapping layer, i.e., a trap-rich layer. However, this type of substrate is incompatible with use of transistors the threshold voltage of which may be controlled via a back-side gate (back bias voltage).

Specifically, the presence of this layer containing trapped charges hinders back biasing (application of a potential difference to the back side) and may furthermore lead to an accelerated diffusion of dopants, thus preventing the production of high-quality PN junctions, because of problems with junction leakage.

Apart from FD-SOI structures comprising one BOX layer, FD-SOI structures comprising two BOX layers, which are called “double BOX” structures, have been produced.

The double-BOX technology is advantageous in the case where the FD-SOI structure comprises double-gate transistors the gate electrodes of which are formed both above and below the conduction channel. Thus, the SOI layer of the back gate, which is called the back-gate SOI layer, is electrically separated from the SOI layer of the front gate, which is called the front-gate SOI layer, by a first BOX layer, and is also electrically separated from the basic substrate by a second BOX layer.

Document US 2010/0176482 describes an example of such an FD-SOI structure comprising two BOX layers, for a CMOS technology.

According to this document, CMOS structures with a high-k gate dielectric and with a gate length of as small as 30 nm are fabricated using an optimized process allowing a good isolation between the devices and the back gate to be obtained.

The existing double-BOX technology is used for digital applications, and not both for radiofrequency and digital applications.

### BRIEF SUMMARY

One aim of the present disclosure is to provide a semiconductor-on-insulator structure allowing the aforementioned drawbacks to be overcome. The present disclosure aims to provide such a structure allowing digital applications and radiofrequency applications to be combined.

To this end, the present disclosure provides a semiconductor-on insulator structure comprising:
a stack, called the back stack, of the following layers from a back side to a front side of the structure:
   a semiconductor carrier substrate the electrical resistivity of which is between 500 Ω·cm and 30 kΩ·cm,
   a first electrically insulating layer, and
   a first semiconductor layer,
at least one trench isolation that extends through the back stack at least down to the first electrically insulating layer, and that electrically isolates two adjacent regions of the multilayer structure,

the multilayer structure mainly being characterized in that it furthermore comprises:
at least one FD-SOI first region comprising a stack, called the front stack, arranged on the back stack, the front stack comprising:
   a second electrically insulating layer arranged on the first semiconductor layer, and
   a second semiconductor layer called the active layer, arranged on the second electrically insulating layer,

wherein the first electrically insulating layer has a thickness larger than that of the second electrically insulating layer, and the first semiconductor layer has a thickness larger than that of the active layer, the FD-SOI first region furthermore comprising at least one digital component in the active layer,
at least one RF-SOI second region electrically isolated from the FD-SOI region by a trench isolation, comprising at least one radiofrequency component plumb with the first electrically insulating layer.

According to other aspects, the proposed structure has the following various features, which may be implemented alone or in technically feasible combinations thereof:
the back stack furthermore comprises a charge-trapping layer arranged between the carrier substrate and the first electrically insulating layer;
the charge-trapping layer is made of polysilicon or of porous silicon;
the radiofrequency component is arranged in the first semiconductor layer;
the RF-SOI second region comprises the front stack arranged on the back stack, and wherein the radiofrequency component is arranged in the active layer;
the first semiconductor layer is made of crystalline material;
the first semiconductor layer is made of amorphous material;
the second semiconductor layer is made of crystalline material;
the first electrically insulating layer is a layer of silicon oxide;
the second electrically insulating layer is a layer of silicon oxide;
the first electrically insulating layer has a thickness between 50 nm and 1500 nm;
the second electrically insulating layer has a thickness between 10 nm and 100 nm;
the first semiconductor layer has a thickness between 10 nm and 200 nm;
the active layer has a thickness between 3 nm and 30 nm.

The present disclosure also relates to a process for fabricating a semiconductor-on-insulator multilayer structure, comprising the following steps:
providing a first donor substrate,
forming a weakened zone in the first donor substrate, so as to delineate a first semiconductor layer,
transferring the first semiconductor layer to a semiconductor carrier substrate, a first electrically insulating layer being at the interface between the donor substrate and the carrier substrate so as to form a back stack comprising the carrier substrate, the first electrically insulating layer and the transferred first semiconductor layer,
providing a second donor substrate,
forming a weakened zone in the second donor substrate, so as to delineate a second semiconductor layer, called the active layer,
transferring the semiconductor layer to the back stack, a second electrically insulating layer being at the interface between the second donor substrate and the back stack, so as to form a front stack comprising the second electrically insulating layer and the transferred second semiconductor layer,
forming at least one trench isolation that extends through the front stack and through the back stack at least down to the first electrically insulating layer, in order to electrically isolate two adjacent regions, including at least one FD-SOI region and at least one RF-SOI region,
producing:
   at least one digital component in the active layer, in the FD-SOI region, and
   at least one radiofrequency component plumb with the first electrically insulating layer.

The present disclosure also relates to a process for fabricating a semiconductor-on-insulator multilayer structure, comprising the following steps:
forming a back stack by depositing a first semiconductor layer on a carrier substrate covered with a first electrically insulating layer,
providing a donor substrate,
forming a weakened zone in the donor substrate, so as to delineate a second semiconductor layer,
transferring the second semiconductor layer to the back stack, a second electrically insulating layer being at the interface between the second donor substrate and the back stack, so as to form a front stack on the back stack,
forming at least one trench isolation that extends through the front stack and through the back stack at least down to the first electrically insulating layer, in order to electrically isolate two adjacent regions, including at least one FD-SOI region and at least one RF-SOI region,
producing:
   at least one digital component in the active layer, in the FD-SOI region, and
   at least one radiofrequency component plumb with the first electrically insulating layer.

According to other aspects, the proposed processes have the following various features, which may be implemented alone or in technically feasible combinations thereof:
the method comprises, before the radiofrequency component is produced, a step of selectively removing the active layer and the second electrically insulating layer of the RF-SOI region, and wherein the radiofrequency component is then formed in the first semiconductor layer;
the process furthermore comprises, before the transferring step, forming a charge-trapping layer on the receiver substrate, the charge-trapping layer being arranged between the carrier substrate and the first electrically insulating layer.

The multilayer structure of the present disclosure serves as carrier for the fabrication of transistors, in particular, MOSFETs. MOSFETs are semiconductor devices comprising three active electrodes, namely an input electrode called the gate, an output electrode called the drain, and a third electrode called the source. These transistors allow a voltage (or a current) output on the drain to be controlled by virtue of the gate.

In the present text, the term “on”, when it relates to the position of a first layer with respect to a second layer, or the position of a component with respect to a layer, does not necessarily imply that the first layer makes direct contact with the second or that the component makes direct contact with the layer. Unless otherwise specified, this term does not exclude one or more other layers being intermediate between the first layer and second layer, or between the component and the layer.

### BRIEF DESCRIPTION OF THE DRAWINGS

Other advantages and features of the present disclosure will become apparent upon reading the following description given by way of illustrative and non-limiting example, with reference to the following accompanying figures:

FIG. 1 is a schematic of a first embodiment of a multilayer structure according to the present disclosure, comprising two FD-SOI regions and one RF-SOI region, in which a digital component is produced in the active layer of the FD-SOI regions and a radiofrequency component is produced in the active layer of the RF-SOI region;

FIG. 2 is a schematic of a second embodiment of a multilayer structure according to the present disclosure, comprising two FD-SOI regions and one RF-SOI region, in which a digital component is produced in the active layer of the FD-SOI regions and a radiofrequency component is produced in the first semiconductor layer of the RF-SOI region;

FIG. 3A is a schematic illustrating the formation of a weakened zone in a first donor substrate;

FIG. 3B is a schematic of a back stack obtained after bonding the first semiconductor layer to the receiver substrate;

FIG. 3C is a schematic illustrating the formation of a weakened zone in a second donor substrate;

FIG. 3D is a schematic of a structure obtained after bonding the second semiconductor layer to the back stack;

FIG. 3E shows a multilayer structure obtained using the fabricating process according to a first embodiment;

FIG. 4A shows a multilayer structure in which a segment of the active layer and of the second electrically insulating layer has been locally removed to form a cavity;

FIG. 4B shows the structure of FIG. 4A, obtained using the fabricating process according to a second embodiment;

FIG. 5A shows a structure equipped with trench isolations;

FIG. 5B shows the structure of FIG. 5A, in which a lateral segment of the first semiconductor layer has been locally removed in order to form a cavity, according to a third embodiment of the fabricating process;

FIG. 5C shows the structure of FIG. 5B, in which the cavity has been filled with a third electrically insulating layer.

### DETAILED DESCRIPTION

A first subject of the present disclosure relates to a semiconductor-on-insulator multilayer structure that is usable both for digital applications and for radiofrequency applications.

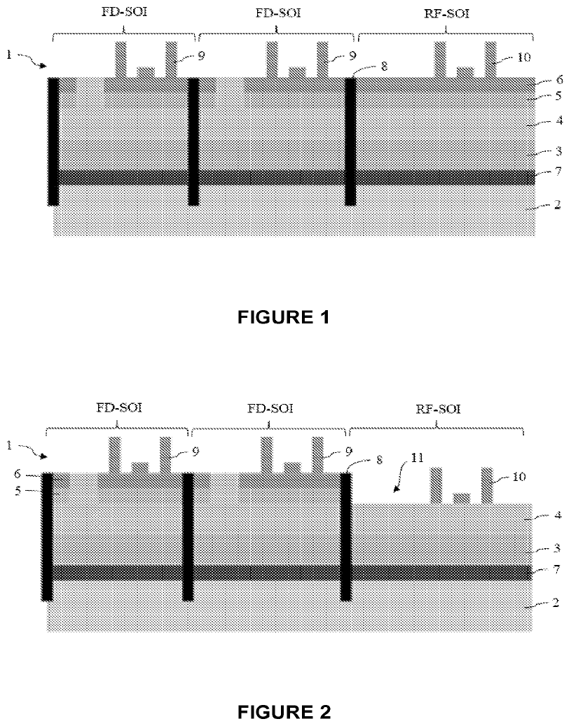

FIG. 1 illustrates a first embodiment of such a multilayer structure 1 according to the present disclosure.

With reference to FIG. 1, the multilayer structure 1 comprises a stack, called the back stack, from a back side to a front side of the structure, of a semiconductor carrier substrate 2, a first electrically insulating layer 3, and a first semiconductor layer 4.

The semiconductor carrier substrate 2 is a highly resistive substrate, i.e., it has an electrical resistivity between 500 Ω·cm and 30 kΩ·cm, and preferably between 1 kΩ·cm and 10 kΩ·cm. A high resistivity gives the carrier substrate the ability to limit electrical losses and to improve the radiofrequency performance of the structure.

The first electrically insulating layer 3 allows the carrier substrate 2 to be insulated from the first semiconductor layer 4 and from the layers superjacent the first semiconductor layer.

The first electrically insulating layer 3 is preferably a layer of oxide. Since this layer is buried in the structure between the carrier substrate 2 and the first semiconductor layer 4, it may also be called the “first BOX”. It is preferably a layer of silicon oxide.

The thickness of the first electrically insulating layer 3 is relatively large, and preferably between 50 nm (nanometers) and 1500 nm. Specifically, too small a thickness, in particular, one smaller than 50 nm, would run the risk of breakdown in the first electrically insulating layer.

Optionally, the structure 1 also comprises a charge-trapping layer 7, which is preferably made of polysilicon or of porous silicon, arranged between the carrier substrate 2 and the first electrically insulating layer 3. This charge-trapping layer allows the electrical charge that accumulates under the first electrically insulating layer 3 to be trapped.

The first semiconductor layer 4 is an intermediate layer arranged between the first electrically insulating layer 3 and a second electrically insulating layer 5, which is described in more detail below in the present text. It preferably has a thickness between 10 nm and 200 nm.

The semiconductor layer 4 is advantageously made of a crystalline material or of an amorphous material, which may optionally be doped in the FD-SOI regions. This material is chosen so that the semiconductor layer in the FD-SOI regions can be biased in order to control the threshold voltage of the transistor (back bias voltage).

Preferably, the material of the semiconductor layer 4 is not doped in the RF-SOI regions in order to optimize the electrical resistivity of the back stack and to thus limit electrical losses.

The material of the semiconductor layer 4 is preferably chosen from: single-crystal silicon, polysilicon, and silicon-germanium.

The multilayer structure 1 comprises a plurality of regions intended for different applications, including at least one FD-SOI region for digital applications and at least one RF-SOI region for radiofrequency applications.

In order to be able to combine an FD-SOI region and an RF-SOI region in one and the same structure, the nature of the constituent layers of the stack located on the first semiconductor layer, called the front stack, is different depending on whether the stack forms part of an FD-SOI region or of an RF-SOI region.

According to the first embodiment illustrated in FIG. 1, the two FD-SOI regions and the RF-SOI region comprise the same front stack. This front stack comprises a second electrically insulating layer 5 arranged on the first semiconductor layer 4, and a second semiconductor layer 6 called the active layer arranged on the second electrically insulating layer 5.

The structure 1 furthermore comprises trench isolations 8 that extend from the free surface of the active layer 6, through the thickness of the structure. The trenches pass through the active layer 6 and the second electrically insulating layer 5 of the front stack, and extend through the back stack at least down to the first electrically insulating layer 3. The trenches may extend more deeply into the back stack, so as to pass through the charge-trapping layer 7 when the latter is present, and the carrier substrate 2.

Each trench isolation electrically isolates two adjacent regions of the structure 1. A trench thus separates two FD-SOI regions, or two RF-SOI regions, or indeed one FD-SOI region and one RF-SOI region.

In the structure of FIG. 1, the second electrically insulating layer 5 extends over the first semiconductor layer 4, both within the FD-SOI regions and within the RF-SOI region.

The second electrically insulating layer 5 allows the active layer 6 to be insulated from the first semiconductor layer 4 and from the layers subjacent the intermediate layer.

The second electrically insulating layer 5 is preferably a layer of oxide. Since this layer is buried in the structure between the first semiconductor layer 4 and the active layer 6, it may also be called the “second BOX”. It is preferably a layer of silicon oxide.

The active layer 6 has a thickness that is relatively small, and smaller than that of the first electrically insulating layer 3. This small thickness makes it possible to be able to control the threshold voltage of the transistor via suitable biasing of the subjacent first semiconductor layer 4. A thickness of the second electrically insulating layer 5 is preferably between 10 nm and 100 nm for this reason.

The second semiconductor layer 6 is called the active layer because it is intended for the production both of digital components 9 and of radiofrequency components 10, the components produced depending on the digital and radiofrequency applications desired for the structure 1.

The active layer 6 is preferably made of crystalline material, and more preferably is a layer of single-crystal silicon.

The thickness of the active layer 6 is preferably between 3 nm and 30 nm, and more preferably between 5 nm and 20 nm. It is preferable for the thickness of the active layer to be uniform over all the extent of the material, i.e., for it its thickness to vary by 1 nm or less, in order to optimize the operation of the FD-SOI regions, in a fully depleted mode.

According to the first embodiment shown in FIG. 1, the radiofrequency components are produced on the front stack and in the active layer 6.

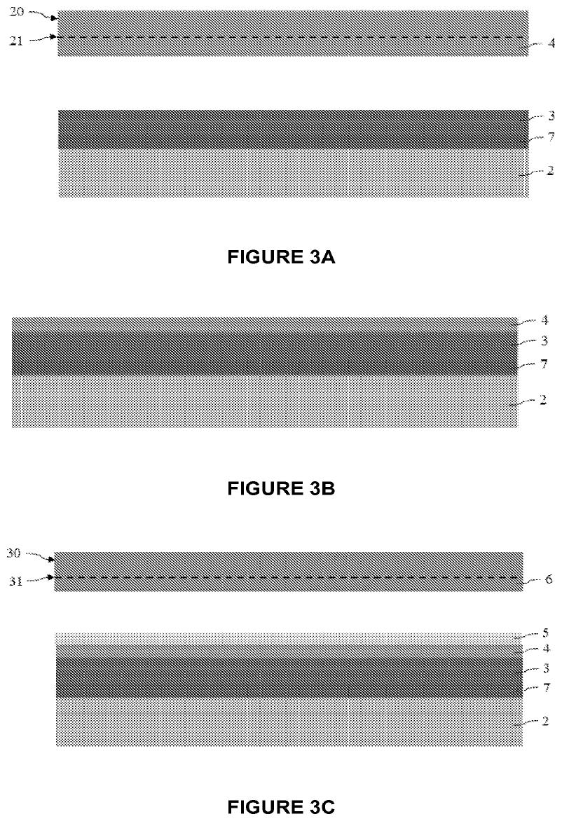

FIG. 2 illustrates a second embodiment of the multilayer structure 1 according to the present disclosure.

This second embodiment differs from the first in that the front stack described above is present solely in the FD-SOI regions, and the radiofrequency components are arranged directly in the first semiconductor layer 4 of the RF-SOI region.

With reference to FIG. 2, the RF-SOI region thus comprises neither the second electrically insulating layer 5 arranged on the first semiconductor layer 4, nor the active layer 6 arranged on the second electrically insulating layer 5. Specifically, the first electrically insulating layer 3 already allows, without the presence of the second electrically insulating layer 5, a structure to be obtained that is resistive enough to limit electrical losses.

Three embodiments of a process for fabricating a multilayer structure 1 such as described above will now be described.

According to a first embodiment, a first donor substrate 20 is initially provided.

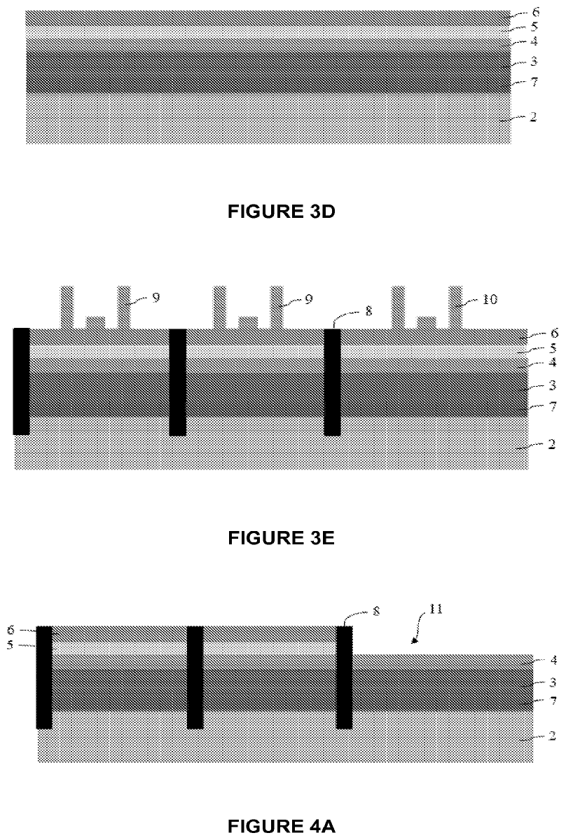

With reference to FIG. 3A, a weakened zone 21 is formed in this substrate, so as to delineate a first semiconductor layer 4. The weakened zone 21 is formed in the donor substrate at a predefined depth that corresponds substantially to the thickness of the semiconductor layer to be transferred. Preferably, the weakened zone 21 is created by implanting hydrogen and/or helium atoms into the donor substrate 20.

The first semiconductor layer 4 is then transferred to a semiconductor carrier substrate 2, which is a receiver substrate, by bonding the donor substrate 20 to the carrier substrate via the first electrically insulating layer 3 then by detaching the donor substrate along the weakened zone 21 (Smart Cut™ process). The first electrically insulating layer may be formed on the donor substrate or on the carrier substrate.

Alternatively, the transfer may be achieved by thinning the donor substrate 20 from the side thereof opposite the side bonded to the carrier substrate 2, until the thickness desired for the first semiconductor layer 4 is obtained.

Optionally, before the bonding step, a charge-trapping layer 7 is formed on the carrier substrate 2, between the carrier substrate and the first electrically insulating layer 3.

A back stack, such as described above and shown in FIG. 3B, comprising the carrier substrate 2, the charge-trapping layer 7 when present, the first electrically insulating layer 3 and the transferred first semiconductor layer 4, is then obtained.

Moreover, a second donor substrate 30 is provided.

With reference to FIG. 3C, a weakened zone 31 is formed in this substrate, so as to delineate a second semiconductor layer 6. The weakened zone may be formed in the same way used to delineate the first semiconductor layer.

The second semiconductor layer 6 is then transferred to the back stack, which forms a receiver substrate, by bonding the second donor substrate to the back stack via the second electrically insulating layer 5 then by detaching the donor substrate along the weakened zone (Smart Cut™ process). The second electrically insulating layer 5 may be formed on the donor substrate or on the receiver substrate.

With reference to FIG. 3D, a front stack positioned on the back stack and comprising the second electrically insulating layer 5 and the second semiconductor layer 6, is then obtained.

Alternatively, the transfer may be achieved by thinning the second donor substrate 30 from the side thereof opposite the side bonded to the back stack, until the thickness desired for the second semiconductor layer 6 is obtained.

Optionally, before the transferring step, it is possible to carry out a treatment of the free surface of the first semiconductor layer in order to decrease the roughness thereof. This surface treatment improves the bonding of the second electrically insulating layer to the first semiconductor layer.

With reference to FIG. 3E, the trench isolations 8, which extend through the front stack and through the back stack at least down to the first electrically insulating layer 3, are then formed, in order to electrically isolate two adjacent regions, in particular, an FD-SOI region and an RF-SOI region.

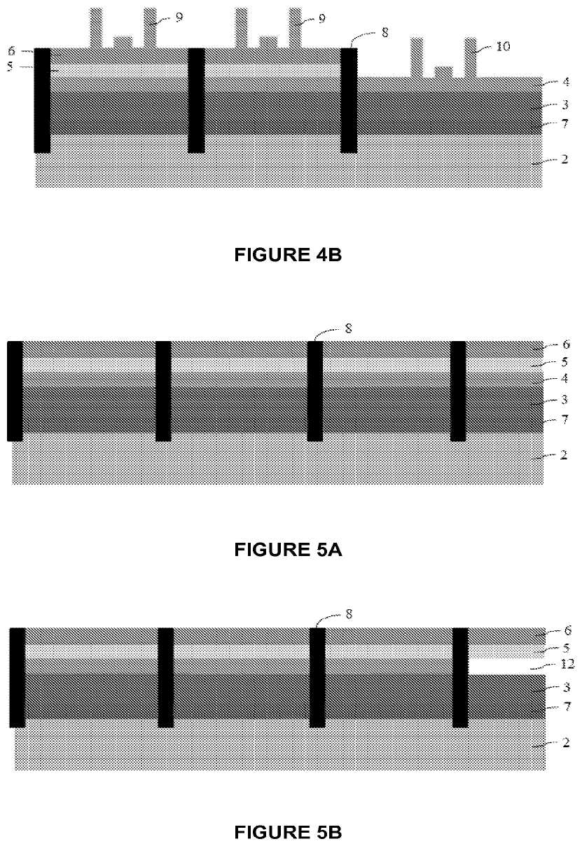

In the case where it is desired to obtain the structure of FIG. 2, before the radiofrequency components 10 are produced and preferably before the digital components 9 are produced, a segment of the active layer 6 and of the second electrically insulating layer 5 of the RF-SOI regions is selectively removed in order to form a cavity 11. This is shown in FIG. 4A.

The local removal may advantageously be carried out by etching. To this end, a lithography mask is deposited on the active layer 6. The mask is provided with at least one aperture. The active layer 6 is then etched through the aperture of the mask in order to form the cavity 11. Any known etching technique suitable for this purpose is usable, such as, for example, dry etching with hydrochloric acid.

The digital components 9 are produced on the second semiconductor layer 6, which is the active layer. This allows an FD-SOI region to be obtained.

The radiofrequency components 10 are also produced, on the first semiconductor layer. The radiofrequency components may be produced in the active layer 6 (FIG. 1) or in the first semiconductor layer 4 (FIG. 2 and FIG. 4B). This allows an RF-SOI region to be obtained.

The first embodiment that has just been described comprises two steps of delineating and transferring a semiconductor layer. This is most particularly advantageous in the case where the first semiconductor layer is crystalline. The transfer of such a layer from a donor substrate allows its crystal quality to be preserved on the final structure.

When an optimization of the crystal quality of the first semiconductor layer is not required, for example, when the latter is amorphous, it is possible to form the first semiconductor layer by deposition on the first electrically insulating layer. This process then employs only a single transferring step, i.e., the step of transferring the active layer, and is therefore more economical.

This method corresponds to a second embodiment that will now be described.

According to a second embodiment, a back stack is formed by depositing a first semiconductor layer 4 on a carrier substrate 2 covered beforehand with a first electrically insulating layer 3. This back stack is illustrated in FIG. 3B.

The first semiconductor layer 4 may be formed by epitaxy on the carrier substrate, or alternatively deposited on the carrier substrate, in particular, by chemical vapor deposition (CVD).

Optionally, before the deposition of the first semiconductor layer, a charge-trapping layer 7 is formed on the carrier substrate 2, between the carrier substrate and the first electrically insulating layer 3.

Moreover, a donor substrate 30 is provided.

With reference to FIG. 3C, a weakened zone 31 is formed in this donor substrate, so as to delineate a second semiconductor layer 6. The weakened zone may be formed in the same way used for the first embodiment.

The second semiconductor layer 6 is then transferred to the back stack by bonding the donor substrate to the back stack via the second electrically insulating layer 5 then by detaching the donor substrate along the weakened zone (Smart Cut™ process).

With reference to FIG. 3D, a front stack positioned on the back stack and comprising the second electrically insulating layer 5 and the second semiconductor layer 6, is then obtained.

Alternatively, the transfer may be achieved by thinning the donor substrate 30 from the side thereof opposite the side bonded to the back stack, until the thickness desired for the second semiconductor layer 6 is obtained.

Optionally, before the transferring step, it is possible to carry out a treatment of the free surface of the first semiconductor layer in order to decrease the roughness thereof. This surface treatment improves the bonding of the second electrically insulating layer to the first semiconductor layer, this being particularly advantageous when, as in the present embodiment, the first semiconductor layer is formed by deposition and not by Smart-Cut™ transfer.

With reference to FIG. 3E, the trench isolations 8, which extend through the front stack and through the back stack at least down to the first electrically insulating layer 3, are then formed, in order to electrically isolate two adjacent regions, in particular, an FD-SOI region and an RF-SOI region.

In the case where it is desired to obtain the structure of FIG. 2, before the radiofrequency components 10 are produced and preferably before the digital components 9 are produced, a segment of the active layer 6 and of the second electrically insulating layer 5 of the RF-SOI regions is selectively removed in order to form a cavity 11. This is shown in FIG. 4A.

The local removal may advantageously be carried out by etching, similarly to the first embodiment.

The digital components 9 are produced on the second semiconductor layer 6, which is the active layer. This allows an FD-SOI region to be obtained.

The radiofrequency components 10 are also produced on the first semiconductor layer. The radiofrequency components may be produced in the active layer 6 (FIG. 1) or in the first semiconductor layer 4 (FIG. 2 and FIG. 4B). This allows an RF-SOI region to be obtained.

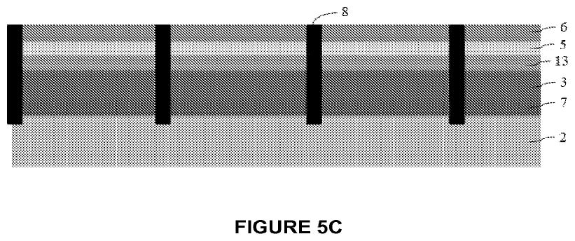

According to a third embodiment, the fabricating process comprises the same steps as those of the first embodiment or those of the second embodiment, in order to form the structure of FIG. 1 comprising the semiconductor carrier substrate 2, the first electrically insulating layer 3, the first semiconductor layer 4, the second electrically insulating layer 5 and the active layer 6. This structure is shown in FIG. 5A.

However, contrary to these two embodiments, a segment of the first semiconductor layer 4 is removed locally. This local removal may be carried out before the radiofrequency components 10 and optionally the digital components are produced on the active layer 6, or indeed after the radiofrequency components 10 and optionally the digital components have been produced on the active layer 6, i.e., during the fabrication of the transistor. It may, in particular, be a question of a MOS transistor, such as a CMOS transistor.

According to this third embodiment, with reference to FIG. 5A, a trench 8 is dug at a defined distance from the edge of the structure, so that the trench extends from the free surface of the active layer 6, through the second electrically insulating layer 5 and the first semiconductor layer 4, down to the first electrically insulating layer 3. This allows the lateral segment delineated by the trench 8 to be physically isolated from the rest of the structure.

With reference to FIG. 5B, the first semiconductor layer 4 in the lateral segment is then locally removed in order to form a cavity 12.

The cavity 12 is a lateral cavity, located on the edge of the useful zone, and opens onto the exterior of the structure. It is bounded in the thickness of the structure by the first electrically insulating layer 3 and the second electrically insulating layer 5, and laterally by the trench 8.

With reference to FIG. 5C, a third electrically insulating layer 13 is then deposited in the cavity 12, in order to fill the cavity.

One or more radiofrequency components 10 may then be produced on the active layer 6, plumb with the third electrically insulating layer 13. An RF-SOI region is then obtained on the structure edge. The expression “plumb with”, which relates to the position of a component with respect to a layer within a structure, means that the component and the layer face each other in the direction of the thickness of the structure. In other words, any axis that extends through the thickness of the structure and that intercepts the component, also intercepts the layer plumb with this component.

The advantage of producing the third electrically insulating layer during the process for fabricating the transistor is that it makes it possible to use the etch masks of this process and therefore to benefit from an optimal alignment of the various layers of the structure.

According to a fourth embodiment (not shown), the active layer 6, the second electrically insulating layer 5 and the first semiconductor layer 4 are removed locally, so as to form a cavity.

A trench 8 may be dug beforehand in the structure, so that the trench extends from the free surface of the active layer 6, through the second electrically insulating layer 5 and the first semiconductor layer 4, down to the first electrically insulating layer 3. This allows the segment of interest delineated by the trench 8 to be physically isolated from the rest of the structure.

Next, the cavity is filled with an oxide, then passive radiofrequency components (inductors, capacitors, conduction lines) are produced on the oxide layer formed.

These passive radiofrequency components do not require a semiconductor such as silicon. They are produced in the back stack of the circuit, with metal lines (in a dielectric layer, for example). Given that these passive RF components are negatively impacted by electrically conductive materials, they greatly benefit from the high-resistivity substrate and from the charge-trapping layer, and from the removal of the semiconductor layers.

According to a fifth embodiment (not shown) a trench 8 is dug in the structure, so that the trench extends from the free surface of the active layer 6, through the second electrically insulating layer 5 and the first semiconductor layer 4, down to the first electrically insulating layer 3. This allows the segment of interest delineated by the trench 8 to be physically isolated from the rest of the structure.

The active layer 6, the second electrically insulating layer 5 and the first semiconductor layer 4 are removed locally, so as to form a cavity.

Next, passive radiofrequency components are produced in the trench. To this end, it is preferable for the active layer 6 and the second electrically insulating layer 5 to not be too thick. A thickness between 3 nm and 30 nm for the active layer 6 and a thickness between 10 nm and 100 nm for the second electrically insulating layer 5 are suitable for this purpose.

Just like the third embodiment, these embodiments have the advantage of using the etch masks of the process for fabricating the transistor, and therefore of benefiting from an optimal alignment of the various layers of the structure.

1. A semiconductor-on-insulator multilayer structure, comprising:
a back stack including the following layers from a back side to a front side of the structure:
a semiconductor carrier substrate having an electrical resistivity between 500 Ω·cm and 30 kΩ·cm,
a first electrically insulating layer,
a first semiconductor layer,
at least one trench isolation that extends through the back stack at least down to the first electrically insulating layer, the at least one trench isolation electrically isolating two adjacent regions of the multilayer structure,
at least one FD-SOI first region comprising a front stack, the front stack arranged on the back stack, the front stack comprising:
a second electrically insulating layer arranged on the first semiconductor layer,
a second semiconductor layer arranged on the second electrically insulating layer, the second semiconductor layer being an active layer,
wherein the first electrically insulating layer has a thickness larger than that of the second electrically insulating layer, and the first semiconductor layer has a thickness larger than that of the active layer, the FD-SOI first region further comprising at least one digital component in the active layer,
at least one RF-SOI second region electrically isolated from the FD-SOI region by a trench isolation, the at least one RF-SOI second region comprising at least one radiofrequency component plumb with the first electrically insulating layer.

2. The structure of claim 1, wherein the back stack further comprises a charge-trapping layer arranged between the carrier substrate and the first electrically insulating layer.

3. The structure of claim 2, wherein the charge-trapping layer comprises polysilicon or porous silicon.

4. The structure of claim 1, wherein the radiofrequency component is arranged in the first semiconductor layer.

5. The structure of claim 1, wherein the RF-SOI second region comprises the front stack arranged on the back stack, and wherein the radiofrequency component is arranged in the active layer.

6. The structure of claim 1, wherein the first semiconductor layer comprises crystalline material.

7. The structure of claim 1, wherein the first semiconductor layer comprises amorphous material.

8. The structure of claim 1, wherein the second semiconductor layer comprises crystalline material.

9. The structure of claim 1, wherein the first electrically insulating layer is a layer of silicon oxide.

10. The structure of claim 1, wherein the second electrically insulating layer is a layer of silicon oxide.

11. The structure of claim 1, wherein the first electrically insulating layer has a thickness between 50 nm and 1500 nm.

12. The structure of claim 1, wherein the second electrically insulating layer has a thickness between 10 nm and 100 nm.

13. The structure of claim 1, wherein the first semiconductor layer has a thickness between 10 nm and 200 nm.

14. The structure of claim 1, wherein the active layer has a thickness between 3 nm and 30 nm.

15. A method of fabricating a semiconductor-on-insulator multilayer structure, comprising the following steps:
providing a first donor substrate,
forming a weakened zone in the first donor substrate, so as to delineate a first semiconductor layer,
transferring the first semiconductor layer to a semiconductor carrier substrate, a first electrically insulating layer being at an interface between the donor substrate and the carrier substrate so as to form a back stack comprising the carrier substrate, the first electrically insulating layer and the transferred first semiconductor layer,
providing a second donor substrate,
forming a weakened zone in the second donor substrate, so as to delineate a second semiconductor layer, the second semiconductor layer comprising an active layer,
transferring the semiconductor layer to the back stack, a second electrically insulating layer being at the interface between the second donor substrate and the back stack, so as to form a front stack comprising the second electrically insulating layer and the transferred second semiconductor layer,
forming at least one trench isolation that extends through the front stack and through the back stack at least down to the first electrically insulating layer, in order to electrically isolate two adjacent regions, including at least one FD-SOI region and at least one RF-SOI region, and
producing:
at least one digital component in the active layer, within the FD-SOI region, and
at least one radiofrequency component plumb with the first electrically insulating layer.

16. A method of fabricating a semiconductor-on-insulator multilayer structure, comprising the following steps:
forming a back stack by depositing a first semiconductor layer on a carrier substrate covered with a first electrically insulating layer,
providing a donor substrate,
forming a weakened zone in the donor substrate, so as to delineate a second semiconductor layer,
transferring the second semiconductor layer to the back stack, a second electrically insulating layer being at an interface between the donor substrate and the back stack, so as to form a front stack on the back stack,
forming at least one trench isolation that extends through the front stack and through the back stack at least down to the first electrically insulating layer, in order to electrically isolate two adjacent regions, including at least one FD-SOI region and at least one RF-SOI region, and
producing:
at least one digital component in the active layer within the FD-SOI region, and
at least one radiofrequency component on the first semiconductor layer.

17. The method of claim 16, further comprising, before the radiofrequency component is produced, a step of selectively removing the active layer and the second electrically insulating layer within the RF-SOI region, and wherein the radiofrequency component is then formed in the first semiconductor layer.

18. The method of claim 16, further comprising, before the transferring step, forming a charge-trapping layer on the carrier substrate, the charge-trapping layer being arranged between the carrier substrate and the first electrically insulating layer.

19. The method of claim 15, further comprising, before the radiofrequency component is produced, a step of selectively removing the active layer and the second electrically insulating layer within the RF-SOI region, and wherein the radiofrequency component is then formed in the first semiconductor layer.

20. The method of claim 15, further comprising, before the transferring step, forming a charge-trapping layer on the carrier substrate, the charge-trapping layer being arranged between the carrier substrate and the first electrically insulating layer.
